(19) United States
(12) Patent Application Publication
(10) Pub. No.: US 2024/0260413 A1
(43) Pub. Date: Aug. 1, 2024

(54) DISPLAY APPARATUS AND COMPOSITION FOR FORMING BANK

(71) Applicant: Samsung Display Co., Ltd., Yongin-si (KR)

(72) Inventors: Sukhoon Kang, Yongin-si (KR); Hyungguen Yoon, Yongin-si (KR); Israel Esteban Lazo Martinez, Yongin-si (KR); Beomsoo Shin, Yongin-si (KR); Sunghwan Hong, Yongin-si (KR)

(21) Appl. No.: 18/427,157

(22) Filed: Jan. 30, 2024

(30) Foreign Application Priority Data
Feb. 1, 2023 (KR) 10-2023-0013909

(51) Int. Cl. H10K 59/80; H10K 59/122; H10K 59/38; H10K 102/00

(52) U.S. Cl. CPC H10K 59/877; H10K 59/122; H10K 59/38; H10K 59/8792; H10K 2102/331

(57) ABSTRACT

A display apparatus includes a substrate on which a plurality of light-emitting devices are located; a plurality of color conversion layers on the substrate and corresponding to the plurality of light-emitting devices; and a plurality of banks among the plurality of color conversion layers, wherein each of the plurality of banks includes first scattering particles, second scattering particles, and a pigment, and the average diameter (D₅₀) of the first scattering particles and the average diameter (D₅₀) of the second scattering particles are different from each other, and the average diameter of the first scattering particles is at least about 150 nm and at most (e.g., not more than) about 200 nm.

### CROSS-REFERENCE TO RELATED APPLICATION

This application claims priority to and the benefit of Korean Patent Application No. 10-2023-0013909, filed on Feb. 1, 2023, in the Korean Intellectual Property Office, the entire content of which is hereby incorporated by reference.

### BACKGROUND

### 1. Field

One or more embodiments relate to a display apparatus.

### 2. Description of the Related Art

Display apparatuses are devices that visually display data. Display apparatuses may include a substrate partitioned into a display area and a peripheral area. The display area may include scan lines and data lines, which are insulated from each other, and a plurality of pixels. Also, a thin film transistor corresponding to each of the pixels and a pixel electrode electrically connected to the thin film transistor may be provided in the display area. In addition, an opposite electrode commonly provided to the pixels may be provided in the display area. Various wires for transmitting electrical signals to the display area, a scan driving unit, a data driving unit, a control unit, a pad unit, and/or the like may be provided in the peripheral area.

The usage of such display devices has diversified. Accordingly, one or more suitable designs are being attempted to improve the quality of such display devices.

### SUMMARY

Aspects of one or more embodiments of the present disclosure are directed toward a display apparatus in which the color of light emitted from each pixel is clear and for which light extraction efficiency is increased. However, these objectives are examples, and the scope of the present disclosure is not limited thereby.

Additional aspects will be set forth in part in the description which follows and, in part, will be apparent from the description, or may be learned by practice of the presented embodiments of the disclosure.

According to one or more embodiments of the present disclosure, a display apparatus includes a substrate on which a plurality of light-emitting devices are located, a plurality of color conversion layers on (above) the substrate and corresponding to the plurality of light-emitting devices, and a plurality of banks between the plurality of color conversion layers, wherein each of the plurality of banks includes first scattering particles, second scattering particles, and a pigment, the average diameter (D₅₀) of the first scattering particles and the average diameter (D₅₀) of the second scattering particles are different from each other, and the average diameter of the first scattering particles is from at least about 150 nm and at most (e.g., not more than) about 200 nm.

In one or more embodiments, the average diameter of the first scattering particles may be from about 160 nm to about 180 nm, or from about 165 nm to about 175 nm, or about 170 nm. When the average diameter of the first scattering particles satisfies these numerical ranges, the reflectance with respect to light having the wavelength of 450 nm is increased, and thus the light efficiency of the display apparatus can be improved.

In one or more embodiments, the bank may include a first bank layer including the first scattering particles and the second scattering particles, and a second bank layer which is in direct contact with one surface of the first bank layer and includes a pigment.

In one or more embodiments, a thickness of the second bank layer may be smaller than a thickness of the first bank layer.

In one or more embodiments, at least one of the plurality of light-emitting devices includes a light source emitting blue light, and the second bank layer may be closer to the light source than the first bank layer.

In one or more embodiments, the optical density of the first bank layer and the second bank layer may each independently be from about 0.01/μm to about 0.2/μm, and the optical density of the bank may be from about 0.01/μm to about 0.2/μm.

In one or more embodiments, each of the banks may be formed as a single layer. The banks may be integrally formed or may be formed to be spaced apart from each other.

In one or more embodiments, based on the total weight of the bank (of 100 wt %), the sum of the amount of the first scattering particles and the amount of the second scattering particles may be 20 wt % or less, 18 wt % or less, or 15 wt % or less.

In one or more embodiments, based on the total weight of the bank, the sum of the amount of the first scattering particles and the amount of the second scattering particles may be 1 wt % or more, or 3 wt % or more, or 5 wt % or more.

In one or more embodiments, based on the total weight of the bank, the sum of an amount of the first scattering particles and an amount of the second scattering particles may be from about 5 wt % to about 15 wt %.

In one or more embodiments, based on the total weight of the banks, the amount of the pigment may be 3 wt % or less, or 2 wt % or less, or 1 wt % or less.

In one or more embodiments, based on the total weight of the bank, the amount of the pigment may be 0.1 wt % or more, or 0.3 wt % or more, or 0.5 wt % or more.

In one or more embodiments, based on the total weight of the bank, the amount of the pigment may be from about 0.1 wt % to about 3 wt %.

In one or more embodiments, based on 100 parts by weight of the first scattering particles, the amount of the second scattering particles may be from about 10 parts by weight to about 1000 parts by weight.

In one or more embodiments, based on a total of 100 parts by weight of the first scattering particle and the second scattering particle, the amount of the pigment may be 0.01 parts by weight to 20 parts by weight.

In one or more embodiments, the average diameter of the second scattering particles may be at least about 100 nm and less than about 150 nm. When the average diameter of the second scattering particles satisfies the numerical range, the transmittance of the banks with respect to light having a wavelength of 880 nm may be increased, and the formation of the banks having a fine structure may be further facilitated.

In one or more embodiments, the average diameter of the second scattering particles may be greater than about 200 nm and at most (e.g., not more than) about 300 nm. Within this numerical range, the transmittance of the banks with respect to light having a wavelength of 365 nm may be increased, and the uniformity of the cured bank may be improved.

In one or more embodiments, the absolute value of the difference between the average diameter of the first scattering particle and the average diameter of the second scattering particle may be at least 10 nm and at most (e.g., not more than) 200 nm, or may be from about 30 nm to about 130 nm. Within this numerical range, the reflectance with respect to light having a wavelength of 450 nm and the transmittance with respect to light having a wavelength of 880 nm and/or transmittance with respect to light having a wavelength of 365 nm may be uniformly improved. As a result, a dense and substantially uniform bank can be formed, and by utilizing the bank, the light efficiency of the display apparatus may be enhanced.

In one or more embodiments, the first scattering particles may include TiO₂ particles.

In one or more embodiments, the first scattering particles may include (e.g., may each be) a surface-modified particle.

In one or more embodiments, the second scattering particles may include TiO₂ particles.

In one or more embodiments, the second scattering particles may include (e.g., may each be) a surface-modified particle.

In one or more embodiments, the pigment may have a transmittance of 1% or more with respect to light having a wavelength of 880 nm. In one or more embodiments, the pigment may have a transmittance of 10% or more with respect to light having a wavelength of 880 nm. As a result, degradation of key recognition due to the inclusion of the pigment may be limited, and a bank including the pigment may be formed more densely.

In one or more embodiments, the pigment may be black.

In one or more embodiments, the pigment may be to absorb light whose wavelength is included in a wavelength range of about 350 nm to about 650 nm. In one or more embodiments, the pigment may not be carbon black.

In one or more embodiments, the pigment may include an organic polymer, and the pigment may include at least one of (e.g., one selected from) lactam black, perylene black, and/or cyanine black, and, in one or more embodiments, the pigment may include lactam black.

In one or more embodiments, one or more of the banks may further include scattering particles, and the scattering particles may include at least one of (e.g., one selected from) SiO₂, BaSO₄, Al₂O₃, ZnO, and/or ZrO₂.

In one or more embodiments of the present disclosure, a composition for forming a bank according includes first scattering particles, second scattering particles, a pigment, and a solvent, and the average diameter (D₅₀) of the first scattering particles and the average diameter (D₅₀) of the second scattering particles are different from each other, and the average diameter of the first scattering particles may be at least about 150 nm and at most (e.g., not more than) about 200 nm.

In one or more embodiments, the average diameter of the first scattering particles may be from about 165 nm to about 175 nm.

In one or more embodiments, the average diameter of the second scattering particles may be at least about 100 nm and at most (e.g., not more than) about 150 nm, or at least (e.g., greater than) about 200 nm and at most (e.g., not more than) about 300 nm.

In one or more embodiments, the first scattering particles and the second scattering particles may each include TiO₂ particles having different diameters. In one or more embodiments, the first scattering particles and the second scattering particles may independently include spherical TiO₂ particles.

In one or more embodiments, based on the total weight of the composition, the sum of the amount of the first scattering particles and the amount of the second scattering particles may be from about 1 wt % to about 20 wt %.

In one or more embodiments, based on 100 parts by weight of the first scattering particles, the amount of the second scattering particles may be from about 10 parts by weight to about 1000 parts by weight.

In one or more embodiments, based on the total weight of the composition, the amount of the pigment may be from about 0.1 wt % to about 3 wt %. In one or more embodiments, with respect to light having a wavelength of 365 nm, the composition may have a transmittance of 0.01% or more; with respect to light having a wavelength of 450 nm, the composition may have a transmittance of 5% or more, and with respect to light having a wavelength of 880 nm, the composition may have a transmittance of 1% or more.

### BRIEF DESCRIPTION OF THE DRAWINGS

The above and other aspects, features, and/or principles of certain embodiments of the present disclosure will be more apparent from the following description taken in conjunction with the accompanying drawings, in which:

FIGS. 1A and 1B are plan views each schematically illustrating examples of a display apparatus according to one or more embodiments of the present disclosure;

FIGS. 2A and 2B are equivalent circuit diagrams each of any one pixel of a display apparatus according to one or more embodiments of the present disclosure;

FIG. 3 is a cross-sectional view illustrating a portion of a display area of a display apparatus taken along line I-I′ of FIG. 1A, according to one or more embodiments of the present disclosure; and

FIG. 4 is an enlarged view of a portion of FIG. 3, according to one or more embodiments of the present disclosure.

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

The present disclosure may undergo modifications and may have one or more suitable embodiments. Specific embodiments are illustrated in the drawings and described in more detail in the detailed description. Effects and characteristics of the present disclosure, and methods for achieving the same would become clear with reference to embodiments to be described later in more detail together with the drawings. However, the present disclosure is not limited to the embodiments disclosed below and may be implemented in one or more suitable other forms.

Hereinafter, embodiments of the present disclosure will be described in more detail with reference to the accompanying drawings, and when embodiments are described with reference to the drawings, the same or corresponding components are given with the same reference numerals, and overlapping descriptions thereof will not be provided.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

It will be further understood that the terms “comprises,” “comprising,” “includes,” “including,” “have,” and “having” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

In the following embodiments, when a part such as a film, region, component, etc. is described as being on or above another part, this includes a case where a part is directly above the other part or a case where another film, region, component, etc. is interposed therebetween. It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The size of components in the drawings may be exaggerated or reduced for convenience of description. For example, because the size and thickness of each component shown in the drawings are shown for convenience of description, the present disclosure is not necessarily limited thereto.

In the following embodiments, a case where films, regions, components, etc. are connected, includes not only a case where films, regions, and components are directly connected, but also a case where films, regions, and components are indirectly connected with other films, regions, and components interposed therebetween. In the following embodiments, a case where films, regions, components, etc. are electrically connected, includes not only a case where films, regions, and components are directly electrically connected, but also a case where films, regions, and components are indirectly electrically connected with other films, regions, and components interposed therebetween.

Spatially relative terms, such as “below,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the present disclosure, when particles are spherical, “diameter” indicates a particle diameter or an average particle diameter, and when the particles are non-spherical, the “diameter” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D₅₀. D₅₀ refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

A display apparatus is a device that displays an image, and examples thereof are an organic light-emitting display apparatus, an inorganic electroluminescent (EL) display apparatus, and a quantum dot light-emitting display apparatus.

Hereinafter, as a display apparatus according to one or more embodiments, an organic light-emitting display apparatus will be described as an example, but the display apparatus of the present disclosure is not limited thereto, and one or more suitable other types (kinds) of display apparatus may be utilized therefor.

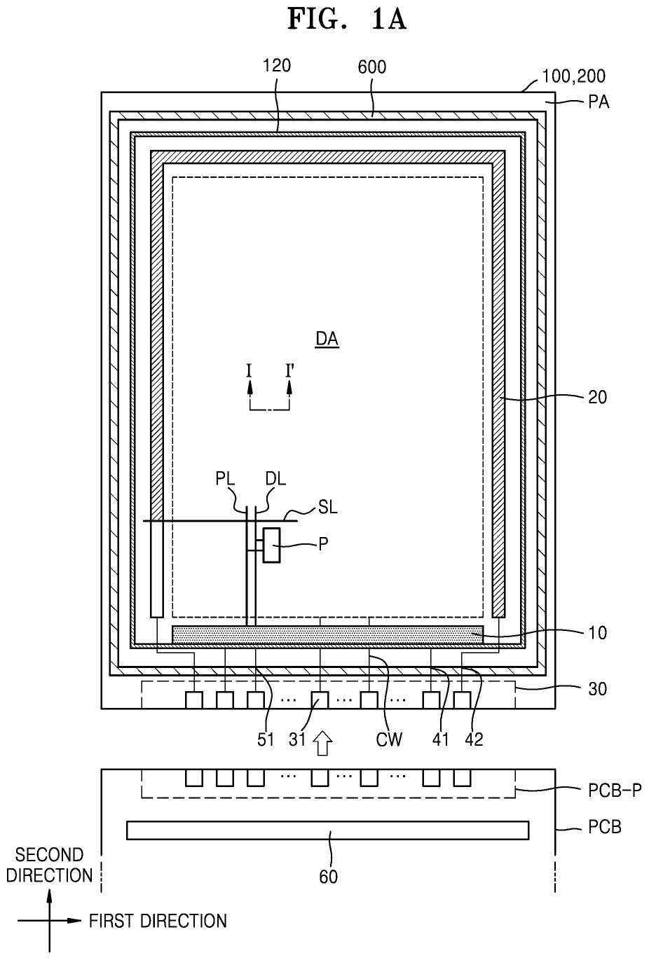

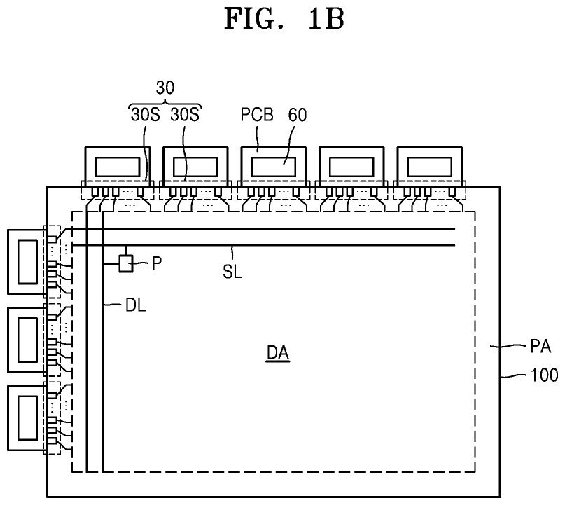

FIGS. 1A and 1B are plan views each schematically illustrating examples of a display apparatus according to one or more embodiments of the present disclosure.

Referring to FIG. 1A, the display apparatus may be formed by bonding a substrate 100 and an upper substrate 200 together by a sealing member 600. The sealing member 600 may be formed to surround the outer surfaces of the substrate 100 and the upper substrate 200 to bond the substrate 100 and the upper substrate 200 together.

In one or more embodiments, the display apparatus includes a display area DA and a peripheral area PA disposed around the display area DA. The display apparatus may provide an image by utilizing light emitted from a plurality of pixels disposed in the display area DA.

The display area DA includes pixels P connected to a scan line SL (e.g., at least one pixel P connected to at least one scan line) extending in a first direction and a data line DL extending in a second direction crossing the first direction. Each of the pixels P is also connected to a driving voltage line PL extending in the second direction.

Each of the pixels P may include a display element, for example, an organic light-emitting diode (OLED) or an inorganic light-emitting diode (ILED). Each pixel P may be to emit, for example, red, green, blue or white light through the display element. The pixel P utilized herein may be understood as a sub-pixel that emits light of any one color of (e.g., selected from) red, green, blue, and/or white. In one or more embodiments, display elements included in pixels P may all emit the same color of light, and the color of each of the pixels P may be implemented by a color filter and/or the like disposed above the display element.

Each of the pixels P may be electrically connected to embedded circuits disposed in the peripheral area PA. A first power supply line 10, a second power supply line 20, and a pad part 30 may be disposed in the peripheral area PA.

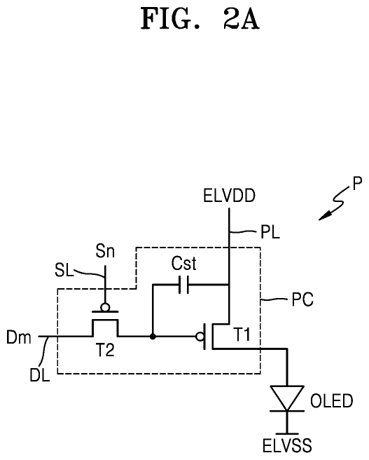

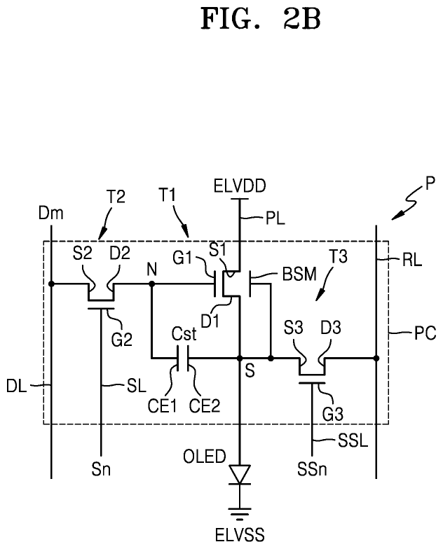

The first power supply line 10 may be arranged to correspond to one side of the display area DA. The first power supply line 10 may be connected to a plurality of driving voltage line PLs that deliver a driving voltage (ELVDD, see, e.g., FIGS. 2A and 2B to be described in more detail later) to the pixels P.

The second power supply line 20 may be around (e.g., may surround), in a loop shape with one side open, a portion (e.g., at least a portion) of the display area DA. The second power supply line 20 may provide a common voltage to the opposite electrode of the pixels P. The second power supply line 20 may be referred to as a common voltage supply line.

The pad part 30 includes a plurality of pads 31 and may be disposed on one side of the substrate 100. Each of the pads 31 may be connected to a first connection wire 41 connected to the first power supply line 10 or connection wires CW extending to the display area DA. The pads 31 of the pad part 30 are exposed without being covered by an insulating layer and may be electrically connected to a printed circuit board PCB. The PCB terminal part PCB-P of the printed circuit board PCB may be electrically connected to the pad part 30.

The printed circuit board PCB may transfer signals or power from a control unit to the pad part 30. The control unit may provide a driving voltage and a common voltage (ELVDD, ELVSS, see, e.g., FIGS. 2A and 2B to be described in more detail later) to the first power supply wire 10 and the second power supply wire 20 through the first connection wire 41 and the second connection wire 42, respectively.

A data driving circuit 60 may be electrically connected to the data line DL (e.g., the data line DL for at least one pixel P). A data signal from the data driving circuit 60 may be provided to each of the pixels P through the connection wire CW connected to the pad part 30 and the data line DL connected to the connection wire CW. FIGS. 1A and 1B illustrate the data driving circuit 60 disposed on the printed circuit board PCB. However, in one or more embodiments, the data driving circuit 60 may be disposed on the substrate 100. For example, the data driving circuit 60 may be disposed between the pad part 30 and the first power supply line 10.

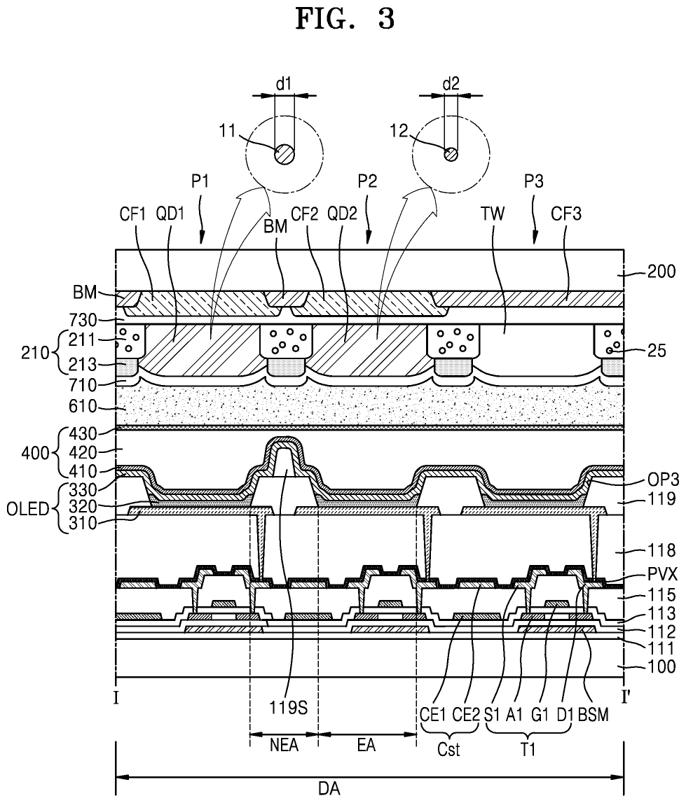

A dam part 120 may be disposed in the peripheral area PA. When an organic encapsulation layer (see, e.g., 420 of FIG. 3) of a thin film encapsulation layer 400 is formed, the dam part 120 may block or reduce the flow of an organic material toward the edge of the substrate 100, preventing or reducing the formation of an edge tail of the organic encapsulation layer 420. The dam part 120 may be disposed to be around (e.g., surround) at least a portion of the display area DA in the peripheral area PA. The dam part 120 may be configured to include a plurality of dams, and when a plurality of dams are disposed, each of the dams may be formed spaced apart from each other. The dam part 120 may be disposed closer to the display area DA than the sealing member 600, in the peripheral area PA. In one or more embodiments, an embedded driving circuit unit for providing a scan signal of each pixel may be further provided in the peripheral area PA. In one or more embodiments, the embedded driving circuit unit and the dam part 120 may overlap each other.

Although FIG. 1A shows that one printed circuit board PCB is attached to the pad part 30, like illustrated in FIG. 1B, a plurality of printed circuit board PCBs may be attached to the pad part 30.

In one or more embodiments, the pad part 30 may be disposed along two sides of the substrate 100. The pad part 30 may include a plurality of sub-pad parts 30S, and one printed circuit board PCB may be attached to each of the sub-pad parts 30S.

FIGS. 2A and 2B are equivalent circuit diagrams each of any one pixel of a display apparatus according to one or more embodiments of the present disclosure.

Referring to FIG. 2A, each of the pixels P includes a pixel circuit PC connected to a scan line SL and a data line DL, and an organic light-emitting diode OLED connected to the pixel circuit PC.

The pixel circuit PC includes a driving thin film transistor T1, a switching thin film transistor T2, and a storage capacitor Cst. The switching thin film transistor T2 is connected to the scan line SL and the data line DL, and may transfer a data signal Dm, which has been input through the data line DL, to the driving thin film transistor T1 according to a scan signal Sn input through the scan line SL.

The storage capacitor Cst is connected to the switching thin film transistor T2 and the driving voltage line PL, and may store a voltage corresponding to the difference between the voltage received from switching thin film transistor T2 and the first power supply voltage (ELVDD, or driving voltage) supplied to the driving voltage line PL.

The driving thin film transistor T1 is connected to the driving voltage line PL and the storage capacitor Cst, and may control the driving current flowing from the driving voltage line PL to the organic light-emitting diode OLED in response to the voltage value stored in the storage capacitor Cst. The organic light-emitting diode OLED may be to emit light having a certain luminance by a driving current.

FIG. 2A illustrates the case where the pixel circuit PC includes two thin film transistors and one storage thin film transistor. However, the present disclosure is not limited thereto.

Referring to FIG. 2B, each of the pixels P may include the organic light-emitting diode OLED and the pixel circuit PC including a plurality of thin film transistors driving the organic light-emitting diode OLED. The pixel circuit PC may include a driving thin film transistor T1, a switching thin film transistor T2, a sensing thin film transistor T3, and a storage capacitor Cst.

Regarding the switching thin film transistor T2, the scan line SL may be connected to a gate electrode G2, the data line DL may be connected to a source electrode S2, and a first electrode CE1 of the storage capacitor Cst may be connected to a drain electrode D2.

Accordingly, the switching thin film transistor T2 supplies the data voltage of the data line DL to a first node N in response to the scan signal Sn from the scan line SL of each of the pixels P.

Regarding the driving thin film transistor T1, a gate electrode G1 may be connected to the first node N, a source electrode S1 may be connected to the driving voltage line PL delivering a driving voltage ELVDD, and a drain electrode D1 may be connected to an anode of the organic light-emitting diode OLED.

Accordingly, the driving thin film transistor T1 may adjust the amount of current flowing through the organic light-emitting diode OLED according to a source-gate voltage Vgs thereof, that is, the voltage applied between the driving voltage ELVDD and the first node N.

Regarding the sensing thin film transistor T3, a sensing control line SSL may be connected to the gate electrode G3, a source electrode S3 may be connected to a second node S, and a drain electrode D3 may be connected to a reference voltage line RL. In one or more embodiments, the sensing thin film transistor T3 may be controlled or selected by the scan line SL instead of the sensing control line SSL.

The sensing thin film transistor T3 may sense the potential of a pixel electrode (for example, an anode) of the organic light-emitting diode OLED. The sensing thin film transistor T3 supplies a pre-charging voltage from a reference voltage line RL to the second node S in response to the sensing signal SSn from the sensing control line SSL, or supplies the voltage of the pixel electrode (for example, anode) of the organic light-emitting diode OLED to the reference voltage line RL during the sensing period.

Regarding the storage capacitor Cst, the first electrode CE1 is connected to the first node N, and a second electrode CE2 is connected to the second node S. The storage capacitor Cst charges a difference voltage between the voltage supplied to the first node N and the voltage supplied to the second node S, and supplies the voltage to the driving thin film transistor T1 as a driving voltage. For example, the storage capacitor Cst may charge a difference voltage between the data voltage Dm and the precharging voltage respectively supplied to the first node N and the second node S.

A bias electrode BSM may be formed to correspond to the driving thin film transistor T1 and may be connected to the source electrode S3 of the sensing thin film transistor T3. Because the bias electrode BSM is supplied with voltage in conjunction with the potential of the source electrode S3 of the sensing thin film transistor T3, the driving thin film transistor T1 may be stabilized. In one or more embodiments, the bias electrode BSM may not be connected to the source electrode S3 of the sensing thin film transistor T3 and may be connected to a separate bias wire.

The opposite electrode (for example, a cathode) of the organic light-emitting diode OLED may receive a common voltage ELVSS. The organic light-emitting diode OLED receives a driving current from the driving thin film transistor T1 and emits light.

Referring to FIG. 2B, each of the pixels includes signal lines SL, SSL, and DL and the reference voltage line RL and the driving voltage line PL. However, the present disclosure is not limited thereto. For example, at least one of the signal lines SL, SSL, and DL, or/and the reference voltage line RL and the driving voltage line PL may be shared by neighboring pixels.

The pixel circuit PC is not limited to the number and circuit design of the thin film transistors and storage capacitors described with reference to FIGS. 2A and 2B, and the number and circuit design can be variously changed.

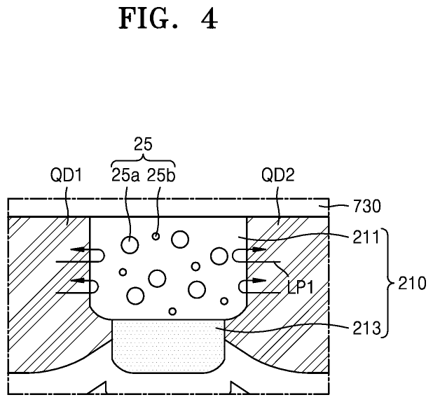

FIG. 3 is a cross-sectional view illustrating a portion of the display area DA of a display apparatus taken along line I-I′ of FIG. 1A, according to one or more embodiments of the present disclosure. FIG. 4 is an enlarged view of a bank 210 illustrated in FIG. 3, according to one or more embodiments of the present disclosure.

Referring to FIG. 3, at least one thin film transistor T1 and a display device connected to the thin film transistor T1 may be disposed in the display area DA of the display apparatus according to one or more embodiments.

FIG. 3 illustrates the driving thin film transistor T1 and the storage capacitor Cst, of the pixel circuit PC of each of the pixels P described with reference to FIGS. 2A and 2B, in the display area DA.

In one or more embodiments, the display area DA of the display apparatus includes a plurality of pixels, and each of the pixels includes an emission area EA. The emission area EA may be an area where light is generated and emitted to the outside. A non-emission area NEA is disposed between emission areas EA, and emission areas EA of the pixels may be defined by the non-emission area NEA.

The plurality of pixels may include a first pixel P1, a second pixel P2, and a third pixel P3, and the first pixel P1, the second pixel P2, and the third pixel P3 may implement light of different colors. For example, the first pixel P1 may implement red light, the second pixel P2 may implement green light, and the third pixel P3 may implement blue light. When viewed on a plane, the emission area EA of each pixel may have one or more suitable polygonal or circular shapes, and may have one or more suitable arrangements such as a stripe arrangement and a PENTILE® arrangement. (PENTILE® is a duly registered trademark of Samsung Display Co., Ltd.).

The display apparatus according to this embodiment may include one or more color conversion layers corresponding to at least one pixel, and the number of each color pixel and the number of color conversion layers corresponding to each of the pixels may be the same as or different from each other.

For example, referring to FIG. 3, a first color conversion layer QD1 and a second color conversion layer QD2 may correspond to the first pixel P1 and the second pixel P2, respectively. The first color conversion layer QD1 and the second color conversion layer QD2 may each include quantum dots and scattering particles.

For example, the first color conversion layer QD1 and the second color conversion layer QD2 may include the first color conversion layer QD1 included in the first pixel P1 and the second color conversion layer QD2 included in the second pixel P2. The first color conversion layer QD1 may include first quantum dots 11, and the second color conversion layer QD2 may include second quantum dots 12.

In one or more embodiments, a color conversion layer does not correspond to the emission area of the third pixel P3, and a transmission window TW may be disposed therein. The transmission window TW may include an organic material capable of allowing light to travel without converting the wavelength of light emitted from the organic light-emitting diode OLED of the third pixel P3.

The organic light-emitting diode OLEDs included in the first pixel P1, the second pixel P2, and the third pixel P3 may be to emit the same color of light. For example, an organic light-emitting diode OLED may be to emit blue light.

Hereinafter, for convenience of description, the configuration disposed in the display area DA of FIG. 3 will be described according to a stacking order.

The substrate 100 may include a glass material, a ceramic material, a metal material, or a material having flexible or bendable characteristics. In the case where the substrate 100 has flexible or bendable characteristics, the substrate 100 may include a polymer resin such as polyethersulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP). The substrate 100 may have a single layer or multi-layer structure of the material. When the substrate 100 has a multi-layer structure, the substrate 100 may further include an inorganic layer. In one or more embodiments, the substrate 100 may have an organic/inorganic/organic structure.

A barrier layer may be further included between the substrate 100 and a first buffer layer 111. The barrier layer may prevent, reduce or minimize penetration of impurities from the substrate 100 into a semiconductor layer A1. The barrier layer may include an inorganic material such as an oxide or nitride, an organic material, or an organic/inorganic composite, and may have a single-layer or multi-layer structure of an inorganic material and an organic material.

A bias electrode BSM may be disposed on the first buffer layer 111 to correspond to the driving thin film transistor T1. A voltage may be applied to the bias electrode BSM. For example, the bias electrode BSM may be connected to the source electrode (see, e.g., S3 of FIG. 2B) of a sensing thin film transistor (see T3 of FIG. 2B), and the voltage of the source electrode S3 may be applied thereto. In one or more embodiments, the bias electrode BSM may prevent or substantially prevent external light from reaching the semiconductor layer A1. Accordingly, characteristics of the driving thin film transistor T1 may be stabilized. In one or more embodiments, the bias electrode BSM may not be provided.

A semiconductor layer A1 may be disposed on a second buffer layer 112. The semiconductor layer A1 may include amorphous silicon or polysilicon. In embodiments, the semiconductor layer A1 may include oxides of at least one material of (e.g., selected from) indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and/or zinc (Zn). In one or more embodiments, the semiconductor layer A1 may be formed utilizing a Zn oxide-based material, such as a Zn oxide, an In—Zn oxide, a Ga—In—Zn oxide, and/or the like. In one or more embodiments, the semiconductor layer A1 may be IGZO (In—Ga—Zn—O), ITZO (In—Sn—Zn—O), or IGTZO (In—Ga—Sn—Zn—O) semiconductor, in which ZnO contains metals such as indium (In), gallium (Ga), and/or tin (Sn). The semiconductor layer A1 may include a channel region, and a source region and a drain region disposed on opposite sides of the channel region. The semiconductor layer A1 may have a single-layer structure or a multi-layer structure.

A gate electrode G1 may be disposed above the semiconductor layer A1 while at least partially overlapping the semiconductor layer A1 with a gate insulating layer 113 interposed therebetween. The gate electrode G1 may include molybdenum (Mo), aluminum (Al), copper (Cu), or titanium (Ti), and may have a single-layer structure or a multi-layer structure. For example, the gate electrode G1 may be a single layer of Mo. A first electrode CE1 of a storage capacitor Cst may be disposed on the same layer as the gate electrode G1. The first electrode CE1 and the gate electrode G1 may include an identical material.

An interlayer insulating layer 115 may be provided to cover the gate electrode G1 and the first electrode CE1 of the storage capacitor Cst. The interlayer insulating layer 115 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), and/or the like.

A second electrode CE2 of the storage capacitor Cst, the source electrode S1, the drain electrode D1, and the data line DL may be disposed on the interlayer insulating layer 115.

The second electrode CE2 of the storage capacitor Cst, the source electrode S1, the drain electrode D1, and the data line DL may include a conductive material including molybdenum (Mo), aluminum (Al), copper (Cu), titanium (Ti), and/or the like, and may have a single-layer or multi-layer structure, including these materials. For example, the second electrode CE2, the source electrode S1, the drain electrode D1, and the data line DL may have a multi-layer structure of Ti/Al/Ti. The source electrode S1 and the drain electrode D1 may be connected to a source region or a drain region of the semiconductor layer A1 through a contact hole.

The second electrode CE2 of the storage capacitor Cst overlaps the first electrode CE1 with the interlayer insulating layer 115 therebetween, thereby forming capacitance. In this case, the interlayer insulating layer 115 may function as a dielectric layer of the storage capacitor Cst.

The second electrode CE2 of the storage capacitor Cst, the source electrode S1, the drain electrode D1, and the data line DL may be covered by an inorganic protective layer PVX.

The inorganic protective layer PVX may be a single film or a multi-layer structure film, each including silicon nitride (SiNx) and/or silicon oxide (SiOx). The inorganic protective layer PVX may be introduced to cover and protect some wires disposed on the interlayer insulating layer 115. Wires formed together with the data line DL in substantially the same process may be exposed in (on) a portion of the substrate 100 (for example, a portion of a peripheral area PA). Exposed portions of the wires may be damaged by an etchant utilized during patterning of a pixel electrode 310, which will be described later. In one or more embodiments, however, the inorganic protective layer PVX covers the data line DL and at least a portion of the wires formed together with the data line DL, so that the wires may be protected from being damaged during the patterning process of the pixel electrode 310.

A planarization layer 118 is disposed on the inorganic protective layer PVX, and an organic light-emitting diode OLED may be disposed on the planarization layer 118.

The planarization layer 118 may be a film including an organic material and having a single-layer structure or a multi-layer structure, and provides a flat upper surface. The planarization layer 118 may include a general-purpose polymer such as benzocyclobutene (BCB), polyimide (PI), hexamethyldisiloxane (HMDSO), polymethylmethacrylate (PMMA), or polystyrene (PS), polymer derivatives having a phenolic group, acrylic polymers, imide-based polymers, arylether-based polymers, amide-based polymers, fluorine-based polymers, p-xylene-based polymers, vinyl alcohol-based polymers, and/or mixtures thereof.

In the display area DA of the substrate 100, an organic light-emitting diode OLED is disposed on the planarization layer 118. The organic light-emitting diode OLED includes the pixel electrode 310, an interlayer 320 including an organic emission layer, and an opposite electrode 330.

The pixel electrode 310 may be a (semi-)transmissive electrode or a reflective electrode. In one or more embodiments, the pixel electrode 310 may include a reflective layer including Ag, Mg, Al, Pt, Pd, Au, Ni, Nd, Ir, Cr, or a compound thereof, and a transparent or translucent electrode layer formed on the reflective layer. The transparent or translucent electrode layer may include at least one of (e.g. one selected) from indium tin oxide (ITO), indium zinc oxide (IZO), zinc oxide (ZnO), indium oxide (In₂O₃), and indium gallium oxide (IGO), and/or aluminum zinc oxide (AZO). In one or more embodiments, the pixel electrode 310 may include the structure of ITO/Ag/ITO.

A pixel defining layer 119 may be disposed on the planarization layer 118, and the pixel defining layer 119 includes an opening corresponding to each sub-pixel in the display area DA, that is, a third opening OP3 exposing at least a central portion of the pixel electrode 310, the opening defining an emission area of pixels. In one or more embodiments, the pixel defining layer 119 may increase a distance between the edge of the pixel electrode 310 and the opposite electrode 330 above the pixel electrode 310 so as to prevent or reduce an arc from occurring at the edge of the pixel electrode 310.

The pixel defining layer 119 may be formed by, for example, spin-coating one or more organic insulating materials of (e.g. selected from) polyimide, polyamide, acrylic resin, benzocyclobutene, and phenol resin.

The interlayer 320 of the organic light-emitting diode OLED may include an organic emission layer. The organic emission layer may include an organic material including a fluorescent or phosphorescent material emitting red, green, blue, or white light. The organic emission layer may include a low-molecular weight organic material or a polymer organic material, and may include a hole transport layer (HTL), a hole injection layer (HIL), an electron transport layer (ETL), and/or an electron injection layer (EIL), etc. may be optionally further disposed below and above the organic emission layer. The interlayer 320 may be disposed to correspond to each of the plurality of pixel electrodes 310. However, the present disclosure is not limited thereto. The interlayer 320 may undergo one or more suitable modifications. For example, the interlayer 320 may include a layer that is integrally formed across the plurality of pixel electrodes 310.

Although FIG. 3 illustrates that the interlayer 320 is provided separately for each of a first pixel P1, a second pixel P2, and a third pixel P3, the present disclosure is not limited thereto. The interlayer 320 may be integrally formed in each of the first pixel P1, the second pixel P2, and the third pixel P3.

In one or more embodiments, the organic light-emitting diode OLEDs included in the first pixel P1, the second pixel P2, and the third pixel P3 may include an organic emission layer emitting the same color of light. For example, the organic light-emitting diode OLEDs included in the first pixel P1, the second pixel P2, and the third pixel P3 may all emit blue light.

The opposite electrode 330 may be a transmissive electrode or a reflective electrode. In one or more embodiments, the opposite electrode 330 may be a transparent or translucent electrode, and may include a metal thin film having a low work function including Li, Ca, LiF/Ca, LiF/Al, Al, Ag, Mg, and/or a compound thereof. In one or more embodiments, a transparent conductive oxide (TCO), such as ITO, IZO, ZnO, or In₂O₃. film may be further disposed on the metal thin film. The opposite electrode 330 is disposed across the display area DA and the peripheral area PA, and may be disposed on the interlayer 320 and the pixel defining layer 119. The opposite electrode 330 may be formed as one body with respect to the plurality of organic light-emitting diode OLEDs to correspond to the plurality of pixel electrodes 310.

A spacer 119S may be further included on the pixel defining layer 119 to prevent or reduce a mark left by a direct contact with masks. The spacer 119S and the pixel defining layer 119 may be formed as one body. For example, the spacer 119S and the pixel defining layer 119 may be formed concurrently (e.g., simultaneously) in substantially the same process utilizing a halftone mask process.

Because the organic light-emitting diode OLED is easily damaged by moisture or oxygen from the outside, the organic light-emitting diode OLED may be covered and protected by the thin film encapsulation layer 400. The thin film encapsulation layer 400 covers the display area DA and may extend to the outside of the display area DA. The thin film encapsulation layer 400 may include at least one organic encapsulation layer and at least one inorganic encapsulation layer. For example, the thin film encapsulation layer 400 may include a first inorganic encapsulation layer 410, an organic encapsulation layer 420, and a second inorganic encapsulation layer 430.

The first inorganic encapsulation layer 410 covers the opposite electrode 330 and may include silicon oxide, silicon nitride, and/or silicon oxynitride. Other layers such as a capping layer may be disposed between the first inorganic encapsulation layer 410 and the opposite electrode 330 as needed. Because the first inorganic encapsulation layer 410 is formed conforming to the structure lying thereunder, the upper surface thereof may not be flat. The organic encapsulation layer 420 covers the first inorganic encapsulation layer 410, and unlike the first inorganic encapsulation layer 410, the upper surface of the organic encapsulation layer 420 may be substantially flat. For example, the upper surface of a portion of the organic encapsulation layer 420 corresponding to the display area DA may be substantially flat. The organic encapsulation layer 420 may include one or more materials of (e.g., selected from) polyethylene terephthalate, polyethylene naphthalate, polycarbonate, polyimide, polyethylene sulfonate, polyoxymethylene, polyarylate, and/or hexamethyldisiloxane. The second inorganic encapsulation layer 430 covers the organic encapsulation layer 420 and may include silicon oxide, silicon nitride, and/or silicon oxynitride.

Through the multi-layer structure of the thin film encapsulation layer 400, even when cracks occur in the thin film encapsulation layer 400, cracks may not be connected between the first inorganic encapsulation layer 410 and the organic encapsulation layer 420 (e.g., extend through the first inorganic encapsulation layer 410 to the organic encapsulation layer 420) or between the organic encapsulation layer 420 and the second inorganic encapsulation layer 430. As a result, it is possible to prevent, reduce or minimize the formation of a path through which moisture or oxygen from the outside penetrates into the display area DA.

A filler 610 may be disposed on the thin film encapsulation layer 400. The filler 610 may act as a buffer against external pressure and/or the like. The filler 610 may include an organic material such as methyl silicone, phenyl silicone, or polyimide. However, the present disclosure is not limited thereto, and the filler 610 may include an organic sealant such as a urethane-based resin, an epoxy-based resin, an acrylic resin, or an inorganic sealant such as silicon.

A first color filter CF1, a second color filter CF2, and a third color filter CF3 and a light blocking pattern BM may be provided on the upper substrate 200 disposed to face the substrate 100. The first color filter CF1, the second color filter CF2, and the third color filter CF3 may be introduced to implement a full-color image, improve color purity, and improve outdoor visibility. The first color filter CF1 may be implemented to have the same color as that of light emitted through the first color conversion layer QD1, the second color filter CF2 may be implemented to have the same color as that of light emitted through the second color conversion layer QD2, and the third color filter CF3 may be implemented to have the same color as that of light emitted through the organic light-emitting diode OLED of the third pixel P3.

The light blocking pattern BM may be disposed among the first color filter CF1, the second color filter CF2, and the third color filter CF3 to correspond to the non-emission area NEA. The light blocking pattern BM is a black matrix and may be a member for enhancing color resolution, and contrast. The light blocking pattern BM may include at least one of black pigment, black dye, and/or black particles. In one or more embodiments, the light blocking pattern BM may include a material such as Cr, CrOₓ, Cr/CrOₓ, Cr/CrOₓ/CrNy, resin (carbon pigment, RGB mixed pigment), graphite, or non-Cr-based material. In one or more embodiments, the light blocking pattern BM may be formed by overlapping at least two of the first color filter CF1, the second color filter CF2, and the third color filter CF3. For example, as a third color filter CF3 is disposed between the first pixel P1 and the second pixel P2, and parts of the first color filter CF1 and the second color filter CF2 overlap with the third color filter CF3, the function as the light blocking pattern BM may be performed.

In one or more embodiments, the organic light-emitting diode OLED is utilized as an example of a display element, but the present disclosure is not limited thereto. For example, the display element may be provided with a micro- or nano-sized inorganic light-emitting diode (ILED).

In one or more embodiments, the first color conversion layer QD1 and the second color conversion layer QD2, the transmission window TW, and a bank 210 may be disposed between the organic light-emitting diode OLED, which is a display element disposed on the substrate 100, and the upper substrate 200.

The first color conversion layer QD1 and the second color conversion layer QD2 may include first quantum dots 11 and second quantum dots 12, respectively. The first quantum dots 11 and the second quantum dots 12 exhibit unique excitation and emission characteristics depending on their material and size, and accordingly, may convert incident light into light of a certain color. Various materials may be utilized for the first quantum dots 11 and the second quantum dots 12. For example, the first quantum dots 11 and the second quantum dots 12 may include (e.g., may be selected from) a Group II-VI compound, a Group III-V compound, a Group IV-VI compound, a Group IV element, a Group IV compound, and/or combinations thereof. Group II-VI compounds may include (e.g., may be selected from): binary compounds including (e.g., selected from) CdSe, CdTe, ZnS, ZnSe, ZnTe, ZnO, HgS, HgSe, HgTe, MgSe, MgS, and/or mixtures thereof; ternary compounds including (e.g., selected from) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or mixtures thereof; and/or quaternary compounds including (e.g., selected from) HgZnTeS, CdZnSeS, CdZnSeTe, CdZnSTe, CdHgSeS, CdHgSeTe, CdHgSTe, HgZnSeS, HgZnSeTe, HgZnSTe, and/or mixtures thereof. Group III-V compounds may include (e.g., may be selected from) binary compounds including (e.g., selected from) GaN, GaP, GaAs, GaSb, AlN, AIP, AlAs, AlSb, InN, InP, InAs, InSb and/or mixtures thereof; ternary compounds including (e.g., selected from) GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb and/or mixtures thereof; and/or quaternary compounds including (e.g., selected from) GaAlNP, GaAlNAs, GaAlNSb, GaAlPAs, GaAlPSb, GaInNP, GaInNAs, GaInNSb, GaInPAs, GaInPSb, InAlNP, InAINAs, InAlNSb, InAlPAs, InAlPSb and/or mixtures thereof. Group IV-VI compounds may include (e.g., may be selected from): binary compounds including (e.g., selected from) SnS, SnSe, SnTe, PbS, PbSe, PbTe, and/or mixtures thereof; ternary compounds including (e.g., selected from) SnSeS, SnSeTe, SnSTe, PbSeS, PbSeTe, PbSTe, SnPbS, SnPbSe, SnPbTe and/or mixtures thereof; and/or quaternary compounds including (e.g., selected from) SnPbSSe, SnPbSeTe, SnPbSTe, and/or mixtures thereof. Group IV compounds may include (e.g., may be selected from) Si, Ge, and/or mixtures thereof. Group IV compounds may be binary compounds including (e.g., selected from) SiC, SiGe, and/or mixtures thereof.

In this case, binary compounds, ternary compounds, or quaternary compounds may be present in a particle at a substantially uniform concentration or may be present at different concentration distributions in substantially the same particle.

The first quantum dots 11 and the second quantum dots 12 may each be formed in a core-shell structure having a core and a shell. The interface between the core and the shell may have a concentration gradient in which the concentration of elements present in the shell decreases toward the center. The shell of a quantum dot may act as a protective layer for maintaining semiconductor properties by preventing or reducing chemical denaturation of the core and/or as a charging layer for imparting electrophoretic properties to the quantum dot. The shell may be a single-layer structure or a multi-layer structure. The interface between the core and the shell may have a concentration gradient in which the concentration of elements present in the shell decreases toward the center. Examples of the shells of the first quantum dots 11 and the second quantum dots 12 include oxides of metals or non-metals, semiconductor compounds, or combinations thereof.

For example, the metal or non-metal oxide may be a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound, such as MgAl₂O₄, CoFe₂O₄, NiFe₂O₄, or CoMn₂O₄, but the present disclosure is not limited thereto.

Examples of the semiconductor compound include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AlSb, and/or the like. However, the present disclosure is not limited thereto.

The first quantum dots 11 and the second quantum dots 12 may each have the size of about 45 nm or less, or about 40 nm or less, or about 30 nm or less, and within these ranges, color purity or color reproducibility may be improved. In one or more embodiments, because light generated through these quantum dots is emitted in all directions, a wide viewing angle may be improved.

In one or more embodiments, the shapes of the first quantum dots 11 and the second quantum dots 12 are those commonly utilized in the art. For example, the first quantum dots 11 and the second quantum dots 12 may be, but are not limited to, spherical, pyramidal, multi-arm, and/or cubic nanoparticles, nanotubes, nanowires, nanofibers, and/or nanoplate-like particles.

The core of each of the first quantum dots 11 and the second quantum dots 12 may have a diameter of about 2 nm to about 10 nm, and when the first quantum dots 11 and the second quantum dots 12 are exposed to light, they may be to emit light of a specific frequency depending on the size of the particle and the type or kind of material constituting the same. Accordingly, the average size of the first quantum dots 11 and the average size of the second quantum dots 12 may be different from each other. For example, the larger the size of the quantum dots, the longer wavelength colors may be emitted. Therefore, the size of a quantum dot may be selected according to the colors of the first pixel P1 and the second pixel P2.

In one or more embodiments, the organic light-emitting diodes OLEDs included in the first pixel P1, the second pixel P2, and the third pixel P3 may be to emit light of the same wavelength, and the colors of the first pixel P1 and the second pixel P2 may be determined according to the color of light emitted from the first quantum dots 11 and the second quantum dots 12. In one or more embodiments, because a color conversion layer is not provided corresponding to the emission area EA of the third pixel P3, the color of the third pixel P3 may be determined by the color of light emitted by the organic light-emitting diode OLED. For example, an organic light-emitting diode OLED may be to emit light having the wavelength corresponding to the color of blue, and the first pixel P1 may implement red, the second pixel P2 may implement green, and the third pixel P3 may implement blue.

In one or more embodiments, the cores of first quantum dots 11 and second quantum dots 12 may include CdSe. At this time, the average size of the core of the first quantum dots 11, for example, an average diameter (d1) thereof may be about 5 nm, and the average diameter (d2) of the core of the second quantum dots 12 may be about 3 nm.

The first color conversion layer QD1 and the second color conversion layer QD2 may further include, in addition to quantum dots, one or more suitable other materials capable of mixing and properly dispersing the same. For example, a solvent, a photoinitiator, a binder polymer, and a dispersing agent may be further included.

A color conversion layer does not correspond to the emission area of the third pixel P3, and the transmission window TW may be disposed therein. The transmission window TW may include an organic material capable of emitting light without converting the wavelength of light emitted from the organic light-emitting diode OLED of the third pixel P3.

The bank 210 may be disposed among the first color conversion layer QD1, the second color conversion layer QD2, and the transmission window TW to correspond to the non-emission area NEA. For example, the bank 210 may be disposed between the first color conversion layer QD1 and the second color conversion layer QD2, and/or between the second color conversion layer QD2 and the transmission window TW.

Organic materials constituting the bank 210 may include a general-purpose polymer such as benzocyclobutene (BCB), polyimide (PI), hexamethyldisiloxane (HMDSO), polymethylmethacrylate (PMMA), and/or polystyrene (PS), polymer derivative(s) having a phenolic group, acrylic polymer(s), imide-based polymer(s), arylether-based polymer(s), amide-based polymer(s), fluorine-based polymer(s), p-xylene-based polymer(s), vinyl alcohol-based polymer(s), and/or mixture(s) thereof.

As illustrated in FIG. 4, the bank 210 may include a pigment, and a first scattering particle 25a and a second scattering particle 25b. The first scattering particle 25a and the second scattering particle 25b may reflect and scatter light incident toward the bank 210 in (in between) the first color conversion layer QD1, the second color conversion layer QD2, and the transmission window TW. In one or more embodiments, the pigment may block or reduce or absorb light incident from an organic light-emitting diode OLED included in an adjacent pixel.

In one or more embodiments, because light emitted from the first color conversion layer QD1 and the second color conversion layer QD2 is emitted through the quantum dots, the light may be emitted in all directions. From among the light, light LP1 traveling toward a first bank layer 211 may be reflected by bank-scattering particles 25 included in the first bank layer 211, and then may enter the first color conversion layer QD1 and the second color conversion layer QD2. Because the reflected light may excite the quantum dots again, light efficiency may be increased. For example, when light having a wavelength of 450 nm is reflected from the bank, light efficiency of the display apparatus may be further increased.

A first passivation layer 710 and a second passivation layer 730 may be respectively provided under and above the first color conversion layer QD1 and the second color conversion layer QD2, the transmission window TW, and the bank 210. The first passivation layer 710 and the second passivation layer 730 may protect the first color conversion layer QD1, the second color conversion layer QD2 and the transmission window TW from being contaminated by other elements disposed thereon and below. The first passivation layer 710 and the second passivation layer 730 may each include an inorganic insulating material. For example, the first passivation layer 710 and/or the second passivation layer 730 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂).

Light incident from the organic light-emitting diode OLED, incident from the color conversion layer, or incident from the transmission window may be reflected by the first scattering particle 25a and the second scattering particle 25b, and in one or more embodiments, due to the light reflected by the first scattering particle 25a and the second scattering particle 25b, the light efficiency of the display apparatus may be increased.

The first scattering particle 25a and the second scattering particle 25b may have a material and a size suitable for reflecting and/or scattering light in a visible light region. Regarding the display apparatus according to one or more embodiments, the average diameter (D₅₀) of the first scattering particles 25a and the average diameter (D₅₀) of the second scattering particles 25b may be different from each other, and the average diameter of the first scattering particles 25a may be at least about 150 nm and at most (e.g., not more than) about 200 nm.

When the average diameter of the first scattering particles 25a satisfies the numerical range, the reflectance of the bank with respect to light having a wavelength of 450 nm may be increased. In one or more embodiments, the reflectance of the bank for light having a wavelength of 450 nm may exceed 50%. As a result, light efficiency of a display apparatus including the bank may be increased.

Also, from the same aspect, the average diameter of the first scattering particles 25a may be from about 160 nm to about 180 nm, or from about 165 nm to about 175 nm, or about 170 nm. In one or more embodiments, when the average diameter of the first scattering particles 25a is about 170 nm, the reflectance of the bank including the first scattering particles 25a may exceed 55%. As a result, light efficiency of a display apparatus including the bank may be further increased.

Also, for example, when only first scattering particles 25a are included in the composition for forming a bank, the transmittance to light having a wavelength of 365 nm may be insufficient. As a result, the composition for forming a bank may not be sufficiently cured, and the uniformity of a bank formed from the composition may be limited.

Thus, the bank includes second scattering particles 25b, and the average diameter of second scattering particles 25b is different from the average diameter of the first scattering particles 25a. By including the second scattering particles 25b having a diameter that is different from that of the first scattering particles 25a, the uniformity and ease of curing of the composition for forming a bank may be enhanced.

Regarding a display apparatus according to one or more embodiments, the average diameter of the second scattering particles 25b may be at least (e.g., greater than) about 200 nm and at most (e.g., not more than) about 300 nm. By including second scattering particles that satisfy these numerical ranges, the transmittance of 20% or more may be obtained with respect to light having a wavelength of 880 nm.

Also, for example, when only first scattering particles 25a are included in the composition for forming a bank, the transmittance to light having a wavelength of 880 nm may be insufficient. As a result, key recognition may be limited during the bank formation process, and formation of a microstructure or nanoscale structure may be limited.

Regarding a display apparatus according to one or more embodiments, the average diameter of the second scattering particles 25b may be at least about 100 nm and less than about 150 nm. By including second scattering particles that satisfy this numerical range, the transmittance of 20% or more and the reflectance of equal to or less than 10% may be obtained with respect to light having a wavelength of 365 nm.

Regarding a display apparatus according to one or more embodiments, based on the total weight of the bank, the sum of an amount of the first scattering particles 25a and an amount of the second scattering particles 25b may be from about 1 wt % to about 20 wt %. By satisfying these numerical ranges, the reflectance and uniformity of the bank may be harmoniously increased. In tone or more embodiments, the sum of the amount of the first scattering particles and the amount of the second scattering particles may be from about 5 wt % to about 15 wt % based on the total weight of the bank.

Also, regarding a display apparatus according to one or more embodiments, based on the total weight of the bank, an amount of the pigment may be from about 0.1 wt % to about 3 wt %.

When the amount of pigment included in the bank exceeds 3 wt %, independent of the amount of the first scattering particle 25a and the amount of the second scattering particle 25b, the transmittance of light having a wavelength of 450 nm is less than about 1%, or substantially 0%. As a result, an increase in light efficiency by the bank may not be confirmed.

Regarding a display apparatus according to one or more embodiments, based on 100 parts by weight of the first scattering particles 25a, the amount of the second scattering particles 25b may be from about 10 parts by weight to about 1000 parts by weight. Within these numerical ranges, the transmittance at 365 nm and/or 880 nm and reflectance at 450 nm may be harmoniously improved. As a result, the uniformity and fineness of the bank may be improved, and at the same time, the light efficiency of the display apparatus including the bank can be improved.

Regarding a display apparatus according to one or more embodiments, based on a total of 100 parts by weight of the first scattering particle 25a and the second scattering particle 25b, the amount of the pigment may be from about 0.01 parts by weight to about 20 parts by weight. Within this numerical range, transmittance of the bank with respect to light having a wavelength of 450 nm may be about 3% or more.

Regarding a display apparatus according to one or more embodiments, the absolute value of the difference between the average diameter of the first scattering particle 25a and the average diameter of the second scattering particle 25b may be at least 10 nm and at most (e.g., not more than) 200 nm, or from about 30 nm to about 130 nm.

In one or more embodiments, the shapes of the first scattering particle and the second scattering particle are not particularly limited as long as they are generally available and/or suitable in the art. In one or more embodiments, the shapes of the first scattering particle 25a and the second scattering particle 25b may be spherical, rod, plate, pyramid, multi-arm, or cubic nanoparticles, nanotubes, nanowires, nanofibers, nanoplatelet particles, and/or the like.

Regarding a display apparatus according to one or more embodiments, the pigment may have a transmittance of 20% or more with respect to light having a wavelength of 880 nm, and the pigment may be to absorb light having a wavelength in a wavelength range of about 350 nm to about 650 nm. When the pigment having the transmittance of 20% or more with respect to light having a wavelength of 880 nm is utilized, deterioration in key recognition due to the inclusion of the pigment may not be caused. As a result, formation of a bank having a fine structure while containing a pigment may be realized.

Regarding a display apparatus according to one or more embodiments, the pigment may be black, red, green, or blue, and the color thereof is not particularly limited.

Regarding a display apparatus according to one or more embodiments, the pigment may not be carbon black. In the case of carbon black, because the transmittance of light having a wavelength of 880 nm is less than 20%, in the case of a composition for forming a bank including carbon black, key recognition may be deteriorated.

Regarding a display apparatus according to one or more embodiments, the pigment may include an organic polymer. For example, the pigment may include at least one of (e.g., one selected from) lactam black, perylene black, and cyanine black. In one or more embodiments, the pigment may include lactam black. By including lactam black, transmittance for light having a wavelength of 880 nm may be 20% or more, and a bank having a dense structure may be formed.

Regarding a display apparatus according to one or more embodiments, one or more of the banks may further include scattering particles, and the scattering particles may not be TiO₂. Examples of the scattering particles may be one or more of (e.g., one or more selected from) SiO₂, BaSO₄, Al₂O₃, ZnO, and/or ZrO₂.

A composition for forming a bank according to one or more embodiments includes first scattering particles 25a, second scattering particles 25b, a pigment, and a solvent, and the average diameter (D₅₀) of the first scattering particles 25a and the average diameter (D₅₀) of the second scattering particles 25b are different from each other, and the average diameter of the first scattering particles 25a may be at least about 150 nm and at most (e.g., not more than) 200 nm. The first scattering particles 25a, the second scattering particles 25b, and the pigment may be understood by referring to the description in connection with the bank according to one or more embodiments.

In a composition for forming a bank according to one or more embodiments, based on the total weight of the composition, the sum of the amount of the first scattering particles 25a and the amount of the second scattering particles 25b may be from about 1 wt % to about 20 wt %, or from about 5 wt % to about 15 wt %.

In the composition for forming a bank according to one or more embodiments, based on 100 parts by weight of the first scattering particles, the amount of the second scattering particles 25b may be from about 10 parts by weight to about 1000 parts by weight, or from about 20 parts by weight to about 500 parts by weight, or from about 50 parts by weight to about 200 parts by weight.

In the composition for forming a bank according to one or more embodiments, the amount of the pigment may be, based on the total weight of the composition, from about 0.1 wt % to about 3 wt %, or about 0.2 wt % to about 2 wt %, or about 0.5 wt % to about 1 wt %. When the amount of the pigment exceeds 3 wt %, the light absorption rate may be high, independent of the amount of the first scattering particles, resulting in low light reuse rate. When the amount of pigment is less than 0.1 wt %, light from adjacent pixels may not be blocked.

A composition for forming a bank according to one or more embodiments may satisfy the following conditions i) to iii): i) with respect to light having a wavelength of 365 nm, the transmittance thereof is 0.01% or more; ii) with respect to light having a wavelength of 450 nm, the transmittance thereof is 5% or more; and iii) with respect to light having a wavelength of 880 nm, the transmittance thereof is 1% or more.

When all conditions i) to iii) are satisfied, a dense and substantially uniform bank may be formed from the composition for forming a bank, and light efficiency of a display apparatus including the bank may be improved.

In one or more embodiments, the composition for forming the bank may include a solvent. The solvent may be any solvent that uniformly dissolves the first scattering particles, the second scattering particles, and a pigment. A non-limiting example of the solvent may include at least one of (e.g., one selected from) propylene glycol monomethyl ether acetate (PGMEA), propylene glycol methyl ether (PGME), ethyl lactate (EL), acetylacetone (AA), butyl acetate (BA), methyl amyl ketone (MAK), diethyl carbonate (DEC), and/or diisobutyl ketone (DIBK).

Also, the composition for forming a bank according to one or more embodiments may include a photosensitive polymer compound. A non-limiting example of the photosensitive polymer compound includes an acrylic polymer, a polyimide polymer, a polyamide polymer, a siloxane polymer, a polymer containing a silazane structure, a polymer containing a photosensitive acrylic carboxyl group, a novolac resin, and/or an alkali solubility resin. In one or more embodiments, the photosensitive polymer compound may be any photosensitive polymer compounds that are utilized in the art in the manufacture of photoresist films.

Also, the composition for forming a bank according to one or more embodiments may further include an additive. The additive may be utilized to adjust the properties of the bank-forming composition and banks obtained from the bank-forming composition. An example of the additive may be a photosensitizer, a dispersant, an adhesive, and/or a leveling agent.

A non-limiting example of the photosensitizer may be a compound obtained by condensation reaction of 2,3,4,4′-tetrhydroxybenzophenone and naphthoquinone 1,2-diazide-5-sulfonylchloride, or a compound obtained by condensation reaction of 4,4′,4,″-ethylidyne tris phenol and naphthoquinone 1,2-diazide-5-sulfonylchloride.

In one or more embodiments, the dispersant may be a surfactant. For example, silicone-based, fluorine-based, ester-based, cationic, anionic, amphoteric, and/or nonionic surfactant(s) may be utilized as the dispersant. These may be utilized alone or in combination of two or more of these.

Examples of surfactants include polyoxyethylene alkyl ethers, polyoxyethylene alkyl phenyl ethers, polyethylene glycol diesters, sorbitan fatty acid esters, fatty acid-modified polyesters, tertiary amine-modified polyurethanes, and/or polyethyleneimines.

In one or more embodiments, a non-limiting example of the adhesive is a rubber-based adhesive, an acrylic adhesive, a vinyl ether-based adhesive, a silicon-based adhesive, a urethane-based adhesive, and/or the like.

In one or more embodiments, a non-limiting example of the leveling agent may be at least one of (e.g., one selected from) hexane, heptane, octane, nonane, decane, undecane, dodecane, tridecane, tetradecane, pentadecane, hexadecane, cetane, heptadecane, octadecane, nonadecane, and/or icosane.

In embodiments in which the photosensitizer is included, about 0.1 parts by weight to about 10 parts by weight of the photosensitizer may be included based on the total weight of the composition for forming a bank. In embodiments in which the dispersant is included, about 0.1 parts by weight to about 10 parts by weight of the dispersant may be included based on the total weight of the composition for forming a bank. In embodiments in which the adhesive is included, about 0.1 parts by weight to about 10 parts by weight of the adhesive may be included based on the total weight of the composition for forming a bank. In embodiments in which the leveling agent is included, about 0.1 parts by weight to about 10 parts by weight of the leveling agent may be included based on the total weight of the composition for forming a bank.

In one or more embodiments, the bank may include: a first bank layer including the first scattering particle 25a and the second scattering particle 25b; and a second bank layer 213 that is in direct contact with the first bank layer 211 and includes a pigment. Accordingly, the light transmittance of the first bank layer 211 may be at least (e.g., greater than) that of the second bank layer 213. In this case, the second bank layer 213 may be disposed closer to the organic light-emitting diode OLED than the first bank layer 211.

An optical density (OD) is a numerical value representing the degree to which a material having a thickness of 1 μm absorbs light, and may satisfy the following formula.

$$O D = {log}_{10} ( 1 / T )$$

wherein T is an optical transmittance.

For example, when a material has a high optical density, the material may be to absorb light well. When the optical density of a material is 0, the light transmittance is 1, that is, the material is transparent to light.

In general, in order to prevent or reduce color mixing between adjacent pixels, the optical density (OD) of the black matrix placed between pixels may be 1.0/μm or higher, and at least 0.3/μm or higher. Because the black matrix absorbs light emitted from adjacent pixels, it may be common to utilize a material having high optical density.

However, because the bank 210 according to one or more embodiments includes the first scattering particles 25a and the second scattering particles 25b, light could be reused by reflection and/or scattering after reaching the first scattering particles 25a and the second scattering particles 25b inside the bank 210, the optical density (OD) of bank 210 may smaller than that of a general black matrix.

Accordingly, in one or more embodiments, the optical density (OD) of the bank 210 may be about 0.01/μm to about 0.2/μm. Also, in one or more embodiments, a minimum width (Wth) of the bank 210 may be 10 μm or more.

When the optical density (OD) of the bank 210 is set to 0, that is, when the bank 210 includes a transparent material, light emitted from the first color conversion layer QD1 is incident on the second color conversion layer QD2, and thus, color mixing may occur. Accordingly, the bank 210 may have a certain optical density (OD) value. Accordingly, the bank 210 may have an optical density value of at least 0.01/μm or more. In this case, the minimum width (Wth) of the bank 210 may be about 10 μm or more.

Even when the minimum width (Wth) of the bank 210 is as small as 10 μm or more, the light transmittance is rapidly reduced. Accordingly, light incident from the second color conversion layer QD2 does not reach the first color conversion layer QD1 and is absorbed by the bank 210. In one or more embodiments, light incident from the organic light-emitting diode OLED of the second pixel P2 may also be absorbed by the bank 210 without reaching the first color conversion layer QD1 of the first pixel P1. Accordingly, when the bank 210 has the optical density of 0.01/μm or more and the minimum width (Wth) of 10 μm or more, color mixing between adjacent pixels may be prevented or reduced.

### EXAMPLES AND COMPARATIVE EXAMPLES

### Example 1

A composition including a photosensitive polymer compound, first scattering particles having an average diameter (D₅₀) of 170 nm, second scattering particles having an average diameter (D₅₀) of 120 nm, a black pigment, and a solvent was prepared. Components of the composition are shown in Table 1.

Composition 1 was coated on a previously prepared substrate, and prebaked at about 90° C. for about 120 seconds. The heat-treated composition was exposed to about 100 mJ of ultraviolet (UV) rays and developed for about 60 seconds. The cured composition was then post-baked at about 230° C., thereby obtaining Bank 1.

### Examples 2 to 10 and Comparative Examples 1 to 3

Banks were formed in substantially the same manner as in Example 1, except that components of the composition shown in Table 1 were utilized.

TABLE 1

| | | First scattering | | Second scattering | | |
|---|---|---|---|---|---|---|
| | | particles | | particles | | |
| | | Average | Parts by | Average | Parts by | Pigment (parts |
| Evaluation target | | diameter | weight | diameter | weight | by weight) |
| Example | 1 | 170 nm | 7.5 | 150 nm | 2.5 | Lactam black |
| | | | | | | (0.25) |
| | 2 | 170 nm | 5 | 150 nm | 5 | Lactam black |
| | | | | | | (0.25) |
| | 3 | 170 nm | 2.5 | 150 nm | 7.5 | Lactam black |
| | | | | | | (0.25) |
| | 4 | 170 nm | 5 | 190 nm | 5 | Lactam black |
| | | | | | | (0.25) |
| | 5 | 170 nm | 5 | 220 nm | 5 | Lactam black |
| | | | | | | (0.25) |
| | 6 | 170 nm | 3 | 220 nm | 4 | Lactam black |
| | | | | | | (0.6) |
| | 7 | 170 nm | 5 | 220 nm | 2 | Lactam black |
| | | | | | | (0.6) |
| | 8 | 170 nm | 3 | 220 nm | 3 | Lactam black |
| | | | | | | (0.6) |
| | 9 | 170 nm | 5 | 220 nm | 5 | Lactam black |
| | | | | | | (0.75) |
| | 10 | 170 nm | 5 | 220 nm | 5 | Lactam black |
| | | | | | | (1.0) |
| Comparative | 1 | 170 nm | 10 | — | | Lactam black |
| Example | | | | | | (0.25) |

| 2 | — | 150 nm | 10 | Lactam black |
|---|---|---|---|---|
| | | | | (0.25) |
| 3 | — | 220 nm | 10 | Lactam black |

(0.25)

### Evaluation Example 1: Evaluation of Transmittance and Reflectance

Thirteen samples each having a thickness of 10 μm and a width of 5×5 cm were prepared from the banks prepared according to the Examples and Comparative Examples. Transmittance and reflectance were evaluated for each sample. The wavelengths of light utilized for evaluation of transmittance were 365 nm and 880 nm. The wavelength of light utilized for evaluation of reflectance was 450 nm. Transmittance and reflectance were analyzed with a spectrophotometer (CM-3600, manufactured by MINOLTA). The evaluation results are shown in Table 2.

TABLE 2

| | | Transmittance (%) | | Reflectance (%) |
|---|---|---|---|---|
| Evaluation target | | @ 365 nm | @ 880 nm | @ 450 nm |
| Example | 1 | 10.6 | 43.4 | 28.6 |
| | 2 | 11.1 | 44.2 | 27.9 |
| | 3 | 11.6 | 45.0 | 27.1 |
| | 4 | 11.3 | 40.5 | 28.3 |
| | 5 | 12.1 | 36.6 | 27.8 |
| | 6 | 8.0 | 37.6 | 18.7 |
| | 7 | 7.6 | 30.6 | 18.3 |
| | 8 | 8.8 | 40.7 | 17.0 |
| | 9 | 6.5 | 27.7 | 18.3 |
| | 10 | 4.2 | 13 | 16.1 |
| Comparative | 1 | 10.1 | 41.6 | 28.9 |
| Example | 2 | 12.0 | 46.7 | 26.8 |
| | 3 | 13.3 | 34.3 | 27.1 |

Referring to Table 2, with respect to light having a wavelength of 365 nm and light having a wavelength of 880 nm, the transmittance of each of the banks according to the Examples was uniformly increased compared to a corresponding bank according to Comparative Examples, and with respect to light having a wavelength of 450 nm, the reflectance of each of the banks according to Examples was increased or equivalent compared to a corresponding bank according to Comparative Examples. For example, with respect to light having a wavelength of 450 nm, the bank of Example 1 had the reflectance being equivalent to the bank of Comparative Example 1, and at the same time, with respect to light having a wavelength of 365 nm and light having a wavelength of 880 nm, the bank of Example 1 had higher transmittance than the bank of Comparative Example 1.

As a result, light efficiency of a display apparatus including the bank may be increased.

### Evaluation Example 2

The change in transmittance and reflectance according to the change in the average diameter of the scattering particles was measured, and results thereof are shown in Table 3. Evaluation of the transmittance and the reflectance was performed in substantially the same way as in Evaluation Example 1.

TABLE 3

| Average diameter of | | |
|---|---|---|
| scattering particles | Reflectance (%) | Transmittance (%) |
| (nm) | @ 450 nm | @ 880 nm |
| 100 | 20.77 | 54.12 |
| 110 | 22.07 | 52.76 |
| 120 | 22.77 | 51.28 |
| 130 | 23.07 | 49.64 |
| 140 | 23.83 | 47.8 |
| 150 | 26.08 | 45.78 |
| 160 | 28.87 | 43.7 |
| 170 | 29.17 | 41.68 |
| 180 | 28.64 | 39.77 |
| 190 | 27.72 | 37.86 |
| 200 | 27 | 36.19 |
| 210 | 26.78 | 34.69 |
| 220 | 27.09 | 33.4 |
| 230 | 26.72 | 32.28 |
| 240 | 26.18 | 31.38 |
| 250 | 25.59 | 30.65 |
| 260 | 25.54 | 30.08 |
| 300 | 24.3 | 24 |

Referring to Table 3, with respect to light having a wavelength of 450 nm, the reflectance (%) of the scattering particles has a maximum value at an average diameter of about 160 nm to about 180 nm. Referring to Table 3, with respect to light having a wavelength of 880 nm, transmittance (%) of the scattering particles increases as the average diameter of the scattering particles decreases. Accordingly, by further including scattering particles having an average diameter of about 160 nm to about 180 nm, that is, first scattering particles, the transmittance and reflectance of the bank may be improved harmoniously.

### Evaluation Example 3

Changes in transmittance and reflectance according to the amount of TiO₂ scattering particles having an average diameter of 170 nm and the amount of a pigment (OBP, organic black pigment) were measured, and results thereof are shown in Table 4. Evaluation of the transmittance and the reflectance was performed in substantially the same way as in Evaluation Example 1. The unit of each amount is parts by weight.

TABLE 4

| Amount of | | | | Reflectance |
|---|---|---|---|---|
| scattering | Amount of | Transmittance (%) | | (%) |
| particles | pigment | @ 365 nm | @ 880 nm | @ 450 nm |
| 5 | 0 | 59.4 | >10 | 35.6 |
| 10 | 0 | 47.5 | >10 | 44.4 |
| 15 | 0 | 43.1 | >10 | 48.4 |
| 20 | 0 | 39.3 | >10 | 51.3 |
| 25 | 0 | — | <10 | — |
| 30 | 0 | — | <10 | — |
| 5 | 0.25 | 16.38 | >10 | 20.43 |
| 10 | 0.25 | 13.31 | >10 | 21.79 |
| 15 | 0.25 | 10.24 | >10 | 23.15 |
| 20 | 0.25 | 7.17 | >10 | 24.51 |
| 25 | 0.25 | 4.1 | <10 | 25.87 |
| 30 | 0.25 | 1.02 | <10 | 27.23 |
| 5 | 0.5 | 9.51 | >10 | 17.1 |
| 10 | 0.5 | 7.51 | >10 | 18 |
| 15 | 0.5 | 5.5 | >10 | 18.9 |
| 20 | 0.5 | 3.5 | >10 | 19.8 |
| 25 | 0.5 | 1.49 | <10 | 20.7 |
| 30 | 0.5 | 0 | <10 | 21.6 |
| 5 | 0.75 | 9.51 | >10 | 15.6 |
| 10 | 0.75 | 7.51 | >10 | 15.9 |
| 15 | 0.75 | 5.5 | >10 | 16.19 |
| 20 | 0.75 | 3.5 | >10 | 16.48 |
| 25 | 0.75 | 1.49 | <10 | 16.77 |
| 30 | 0.75 | 0 | <10 | 17.06 |
| 5 | 1 | 6.8 | >10 | 10.2 |
| 10 | 1 | 4.9 | >10 | 12.6 |
| 15 | 1 | 4.6 | >10 | 14.4 |
| 20 | 1 | 2.7 | >10 | 15.6 |
| 25 | 1 | — | <10 | — |
| 30 | 1 | — | <10 | — |
| 5 | 2 | 5.6 | >10 | 7.1 |
| 10 | 2 | 0.7 | >10 | 8.5 |
| 15 | 2 | 0.2 | >10 | 9.8 |
| 20 | 2 | 0.1 | >10 | 10.7 |
| 25 | 2 | — | <10 | — |
| 30 | 2 | — | <10 | — |
| 5 | 3 | 3.9 | >10 | 6 |
| 10 | 3 | 0.5 | >10 | 7.1 |
| 15 | 3 | 0.5 | >10 | 8 |
| 20 | 3 | 0.5 | >10 | 8.9 |
| 25 | 3 | — | <10 | — |
| 30 | 3 | — | <10 | — |

Referring to Table 4, it can be seen that the transmittance for light of 365 nm and light of 880 nm decreases as the amount of TiO₂ scattering particles increases. In addition, when the amount of TiO₂ scattering particles exceeds 25 parts by weight, it can be seen that the transmittance with respect to light having a wavelength of 880 nm is less than 10%, regardless of the amount of the pigment.

In contrast, it can be seen that the reflectance with respect to light having a wavelength of 450 nm decreases as the amount of pigment increases. In addition, when the amount of pigment is 0.5 or more, it can be seen that the transmittance with respect to light having a wavelength of 365 nm decreases rapidly.

Herein, embodiments of the present disclosure have been described. Such embodiments may be implemented as separate embodiments or may be implemented as embodiments combined with each other.

As described above, banks included in a display apparatus according to the embodiments of the present disclosure include first scattering particles having an average diameter of at least about 150 nm and at most (e.g., not more than) 200 nm, and second scattering particles having an average diameter (D₅₀) which is different from the average diameter (D₅₀) of first scattering particles. Accordingly, the visibility and light efficiency of the display apparatus can be increased.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Descriptions of features or aspects within each embodiment should typically be considered as available for other similar features or aspects in other embodiments. Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A display apparatus comprising:
a substrate on which a plurality of light-emitting devices are located;
a plurality of color conversion layers on the substrate and corresponding to the plurality of light-emitting devices; and
a plurality of banks among the plurality of color conversion layers,
wherein each of the plurality of banks comprises first scattering particles, second scattering particles, and a pigment,
an average diameter (D₅₀) of the first scattering particles and an average diameter (D₅₀) of the second scattering particles are different from each other, and
the average diameter of the first scattering particles is at least about 150 nm and at most about 200 nm.

2. The display apparatus of claim 1, wherein each of the banks is of a single layer.

3. The display apparatus of claim 1, wherein, based on a total weight of the banks, a sum of an amount of the first scattering particles and an amount of the second scattering particles is 20 wt % or less.

4. The display apparatus of claim 1, wherein, based on a total weight of the banks, an amount of the pigment is 3 wt % or less.

5. The display apparatus of claim 1, wherein, based on a total of 100 parts by weight of the first scattering particles and the second scattering particles, an amount of the pigment is about 0.01 parts by weight to about 20 parts by weight.

6. The display apparatus of claim 1, wherein the average diameter of the second scattering particles is at least about 100 nm and at most about 150 nm.

7. The display apparatus of claim 1, wherein the average diameter of the second scattering particles is at least about 200 nm and at most about 300 nm.

8. The display apparatus of claim 1, wherein an absolute value of a difference between the average diameter of the first scattering particles and the average diameter of the second scattering particles is at least about 10 nm and at most about 200 nm.

9. The display apparatus of claim 1, wherein the first scattering particles comprise TiO₂ particles.

10. The display apparatus of claim 1, wherein the second scattering particles comprise TiO₂ particles.

11. The display apparatus of claim 1, wherein the pigment has a transmittance of 1% or more with respect to light having a wavelength of 880 nm.

12. The display apparatus of claim 1, wherein the pigment is black.

13. The display apparatus of claim 1, wherein at least one of the banks further comprises scattering particles.

14. A composition for forming a bank, the composition comprising:
first scattering particles,
second scattering particles,
a pigment, and
a solvent,
wherein an average diameter (D₅₀) of the first scattering particles and an average diameter (D₅₀) of the second scattering particles are different from each other, and
the average diameter of the first scattering particles is at least about 150 nm and at most about 200 nm.

15. The composition of claim 14, wherein
the average diameter of the second scattering particles is at least about 100 nm and at most about 150 nm, or is at least about 200 nm and at most about 300 nm.

16. The composition of claim 14, wherein the first scattering particles and the second scattering particles comprise TiO₂ particles and an average diameter of TiO₂ particles in the first scattering particles is different from an average diameter of TiO₂ particles included in the second scattering particles.

17. The composition of claim 14, wherein, based on a total weight of the composition, a sum of an amount of the first scattering particles and an amount of the second scattering particles is about 1 wt % to about 20 wt %.

18. The composition of claim 14, wherein, based on 100 parts by weight of the first scattering particles, an amount of the second scattering particles is about 10 parts by weight to about 1,000 parts by weight.

19. The composition of claim 14, wherein, based on a total weight of the composition, an amount of the pigment is about 0.1 wt % to about 3 wt %.

20. The composition of claim 14, wherein,
with respect to light having a wavelength of 365 nm, the composition has a transmittance of 0.01% or more; with respect to light having a wavelength of 450 nm, the composition has a transmittance of 5% or more; and with respect to light having a wavelength of 880 nm, the composition has a transmittance of 1% or more.
